(19) United States
(12) Patent Application Publication
(10) Pub. No.: US 2011/0030793 A1
(43) Pub. Date: Feb. 10, 2011

(54) METHOD FOR PRODUCING PHOTOVOLTAIC-GRADE CRYSTALLINE SILICON BY ADDITION OF DOPING IMPURITIES AND PHOTOVOLTAIC CELL

(75) Inventors: Jed Kraiem, Bourgoin Jallieu (FR); Roland Einhaus, Bourgoin Jallieu (FR); Hubert Lauvray, La Garenne Colombes (FR)

Correspondence Address: OLIFF & BERRIDGE, PLC, P.O. BOX 320850, ALEXANDRIA, VA, 22320-4850, US

(73) Assignee: APOLLON SOLAR, Paris (FR)

(21) Appl. No.: 12/937,421

(22) PCT Filed: Mar. 27, 2009
(86) PCT No.: PCT/FR2009/000346

§ 371 Date: Oct. 12, 2010

(30) Foreign Application Priority Data
Apr. 11, 2008 (FR) 08 01998

(51) Int. Cl. H01L 31/0272; H01L 31/18

(52) U.S. Cl. 136/261; 438/97; 257/E31.043

(57) ABSTRACT

Production of photovoltaic grade crystalline silicon is achieved by crystallization of a molten silicon feedstock, the sum of the initial donor doping element and acceptor doping element concentrations whereof is greater than 0.1 ppma, and both the acceptor and donor doping element concentrations whereof are less than 25 ppma. At least a predefined quantity of a doping material having a segregation coefficient of less than 0.1 is added to the feedstock. This addition enables a crystallized silicon to be produced the difference between the donor and acceptor doping profiles whereof is comprised between 0.1 and 5 ppma over at least 50% of the solidified silicon. A silicon presenting a concentration of at least one of the dopants is greater than or equal to 5 ppma and a difference less than or equal to 5 ppma between these two types of dopant is integrated in a photovoltaic cell.

### BACKGROUND OF THE INVENTION

The invention relates to a silicon-base photovoltaic cell.

The invention also relates to a method for producing photovoltaic grade crystalline silicon by crystallizing a molten silicon feedstock.

### STATE OF THE ART

In conventional manner, silicon used in the photovoltaic industry has to meet a certain number of criteria, in particular in terms of purity, i.e. concentrations of doping and metallic impurities that have to be lower than predefined thresholds. Photovoltaic grade silicon is conventionally obtained in the same way as electronic grade silicon from a metallurgical grade silicon that is purified (via its gas phase) by gaseous means. This method is very efficient for eliminating impurities, but it is extremely costly. In consequence, the purification has a high impact on the total costs of the silicon and on its availability on the market.

New techniques are therefore being looked into to reduce the production cost of silicon able to be used by the photovoltaic industry and to offer new procurement channels. These techniques are based on purification of silicon in its liquid phase. These new purification methods do however involve a large number of technological steps which eliminate the different impurities present in the silicon in specific manner.

One of these steps is melting followed by crystallization of the feedstock to produce ingots. During this step, as the impurities are preferably found in the liquid phase, the concentration of impurities in the solidified silicon is lower than the concentration of impurities in the liquid silicon. The affinity of an impurity for the liquid phase compared to the solid phase is measured by the segregation coefficient k of the impurity. The lower this segregation coefficient k, the greater the affinity of the impurity for the liquid phase and the more efficient the purification is.

In an ingot obtained by crystallization of a molten feedstock, the latter therefore is characterized by a progression of the impurity concentrations over its entire height, i.e. throughout its solidification. The concentration profile of a considered impurity in crystallized silicon is represented by Scheil's equation C(x)=k C₀(1−x)^{k-1}

is in which:
k corresponds to the segregation coefficient of the impurity,
x corresponds to the solidification rate, i.e. to the relative position in the crystallized silicon ingot, when x=0 no crystalline silicon is formed and when x=1 all the molten silicon has been transformed into crystalline silicon,
C₀ corresponds to the concentration of the considered impurity in the molten silicon before the beginning of crystallization.

It is also observed that the part of the ingot that corresponds to the beginning of crystallization presents an impurities concentration that is lower than the part that corresponds to the end of solidification. In general manner, each impurity having values of concentration C₀ and segregation coefficient k that are proper thereto, this results in all impurities of the silicon feedstock having different concentration profiles as a function of the solidified height of the ingot.

Furthermore, as the doping impurities present relatively high segregation coefficients, this technique cannot be used for efficient elimination of dopants. Silicon obtained by crystallization of a molten feedstock of metallurgical grade silicon therefore presents concentrations of doping impurities close to those of the initial feedstock. It is moreover known that boron and phosphorus are the most difficult dopants to eliminate, which explains why they are still present in metallurgical grade silicon.

A feedstock containing predefined quantities of boron and phosphorus is melted and then solidified. FIG. 1 illustrates the boron and phosphorus concentration profiles after solidification. As specified in the foregoing, the dopant profiles progress independently from one another according to the segregation coefficient of each element resulting in the formation of a silicon ingot which presents two types of doping. The ingot is first P-type on account of the presence of a majority of P-type dopants (acceptors) in the bottom part, and then N-type due to a preferred segregation of the N-type dopants (donors) in the top part.

Such an ingot presenting different doping types at each of its ends is difficult to manage in a production line. The silicon presenting the doping type that is not sought for is generally rejected. Such a production method is not satisfactory as it results in too great material losses.

The document WO 2007/001184 describes a solidification method of a molten feedstock of metallurgical grade silicon. This method enables a silicon that is essentially P-type or N-type to be obtained by delaying the change of type in the silicon in its solid phase. In this way, a larger proportion of the crystallized silicon, for example 90% of the ingot, is P-type or N-type and the material loss is reduced.

In this method, the boron and phosphorus concentrations of the silicon feedstock are known. The beginning of crystallization from the molten feedstock is performed in a conventional manner. After a predefined quantity has crystallized, boron or phosphorus is added to the liquid phase so as to keep the P-type or N-type doping of the solid phase. In this way, when crystallization takes place, boron is added to the liquid phase to obtain a P-type silicon or phosphorus is added to obtain an N-type silicon.

In this way the liquid phase is enriched, for example with boron, so as to have a boron concentration in the solid phase that is always higher than the phosphorus concentration. The change of type of the crystallized silicon is thereby delayed.

### OBJECT OF THE INVENTION

The object of the invention is to provide a method for producing a crystalline silicon that is in majority of one doping type, that is economical, easy to implement and that presents electrical performances at least compatible with the requirements of the photovoltaic field.

The method according to the invention is characterized in that, the sum of the initial concentrations of donor doping elements and of acceptor doping elements in the silicon feedstock being larger than 0.1 ppma, both the acceptor and donor doping element concentrations being less than 25 ppma, in the silicon feedstock, the method comprises before crystallization of the silicon:
determining the concentrations of donor-type and acceptor-type doping material initially present in the feedstock,
adding at least a predefined quantity of a doping material having a segregation coefficient of less than 0.1 so as to comply, over at least 50% of the crystallized silicon from the beginning of crystallization, either with a first equation for a P-type crystalline silicon

0.1 ppma≦Σk_{d}C_{0d}(1−x)^{k}^{ₐ}⁻¹−Σk_{d}C_{0d}(1−x)^{k}^{_{d}}⁻¹≦5 ppma

or with a second equation for an N-type crystalline silicon

0.1 ppma≦Σk_{d}C_{0d}(1−x)^{k}^{_{d}}⁻¹−ΣkₐC₀ₐ(1−x)^{k}^{ₐ}⁻¹≦5 ppma,
equations in which
kₐ, k_{d} correspond to the segregation coefficients respectively of the acceptor doping elements and of the donor doping elements,
C₀ₐ, C_{0d} correspond respectively to the concentrations of acceptor dopant elements and of donor dopant elements in the molten silicon just before crystallization,
x corresponds to the fraction of crystallized silicon.

It is a further object of the invention to provide a silicon-base solar cell that presents a high conversion efficiency and that is inexpensive.

### BRIEF DESCRIPTION OF THE DRAWINGS

Other advantages and features will become more clearly apparent from the following description of particular embodiments of the invention given for non-restrictive example purposes only and represented in the appended drawings, in which:

FIGS. 1, 3 and 5 represent the donor and acceptor doping atom concentrations versus the height of crystallized silicon with a method according to the prior art,

FIGS. 2, 4, 6 and 7 represent the donor and acceptor doping atom concentrations versus the height of crystallized silicon with a method according to the invention.

### DESCRIPTION OF PREFERRED EMBODIMENTS OF THE INVENTION

A silicon feedstock is placed in a crucible. The feedstock can be constituted solely of metallurgical grade silicon, of purified metallurgical grade silicon, of photovoltaic grade silicon or of microelectronic grade silicon or of silicon rejects of the latter two lines, for example solar grade or highly-doped electronic grade silicon. The feedstock can also be comprised of a mixture of two or more of these types of silicon.

The sum of the initial concentrations of donor and acceptor type dopant materials present in the raw feedstock is larger than or equal to 0.1 atomic ppm (ppma). Each type of dopant, donor and acceptor, further has a maximum concentration of less than 25 ppma. For example, if the feedstock is essentially constituted by metallurgical grade silicon, the donor and acceptor doping atom concentrations are both comprised between 0.1 and 25 ppma. On the contrary, in another example, if the feedstock is essentially constituted by electronic grade silicon but that is very highly doped, one of the two dopant types has a concentration of about 1 ppba and the other can have a concentration equal for example to 10 ppma.

The silicon feedstock is analyzed to determine the different doping impurities initially present in the feedstock and their respective concentrations. The electron donor and acceptor material concentrations are thus determined in the feedstock. In conventional manner, these doping materials are called donors and acceptors.

The different doping impurities of the feedstock having been determined and quantified, the variation of their concentrations is then calculated according to Scheil's law for a crystalline silicon obtained by solidification of the molten feedstock. The different impurities profiles are then split between doping impurities of electron acceptor type and of electron donor type and the global doping profile of the donor and acceptor impurities is then determined for an as-is crystallized silicon.

In this way, the variation of the concentrations of doping atoms of each type, donor C_{d} and acceptor Cₐ, is determined in the crystalline silicon from the initial concentrations of each of the doping elements of the feedstock. From this data, the type of doping, N or P, is determined throughout the silicon if the latter was crystallized as-is.

Classically, the major dopants in the feedstock are boron and phosphorus, but other dopants can also be present in the silicon feedstock, for example gallium, arsenic, bismuth, antimony, tin, indium or aluminium. The different silicon grades that can constitute the feedstock are advantageously chosen so that the boron and phosphorus concentrations are lower than or equal to 25 ppm atomic (ppma).

If the boron and phosphorus concentrations are considerably higher than the concentrations of the other doping impurities, the boron concentration is substantially equal to the concentration of doping atoms of acceptor type Cₐ and the phosphorus concentration is substantially equal to the concentration of doping atoms of donor type C_{d}. Thus, silicon is called P-type silicon in the crystalline silicon areas where the boron concentration is higher than the phosphorus concentration, and inversely silicon is called N-type silicon in the crystalline silicon areas where the boron concentration is lower than the phosphorus concentration.

To obtain a crystalline silicon that is compatible with use in the photovoltaic field, typically defined by a minimum and uniform charge carrier lifetime characteristic, at least one additional doping element having a segregation coefficient of less than 0.1 is added to the feedstock before the beginning of solidification in addition to the initially present dopants. The doping element or the mixture of doping elements can be added to the feedstock before melting of the latter or once melting has been performed, but always before the beginning of crystallization. If a single doping element is added, this doping element is preferably chosen among gallium, indium, antimony and bismuth. These elements are advantageously added to a silicon feedstock that is of P-type, If a mixture of doping elements is added, the mixture contains at least one of these elements and preferably gallium or antimony, and it can also contain boron and/or phosphorus and/or another dopant, for example arsenic, aluminium, indium or bismuth.

By means of this addition of a predefined quantity of at least one doping element, the silicon obtained by crystallization of a molten feedstock is solely P-type or N-type over the largest possible fraction, i.e. over at least 50% of the crystallized silicon, and advantageously over at least 80% of the crystallized silicon, but preferably over at least 90% of the crystallized silicon. The crystalline silicon obtained further presents a concentration difference between the donor and acceptor dopants that is lower than a predefined threshold, whether the crystalline silicon be P-type or N-type. The incorporation profiles of the two types of dopants in the solid phase are therefore controlled throughout the crystallization.

For the crystallized silicon to be able to be used in the photovoltaic industry, the concentration difference in absolute value between donor and acceptor atoms has to be comprised between 0.1 and 5 atomic ppm, i.e. 0.1 ppma<|Ca—Cd|<5 ppma. This concentration difference is sought for over at least 50% of the crystallized silicon, advantageously over at least 80% of the crystallized silicon, but preferably over at least 90% of the crystallized silicon. The concentration difference between the two types of dopants is therefore comprised in absolute value between 0.1 and 5 atomic ppm from the beginning of crystallization through to solidification of at least 50% of the silicon feedstock. The concentration difference between donor and acceptor dopant atoms is preferably comprised between 0.1 and 2 ppma. In even more advantageous manner, the concentration difference between donor and acceptor dopant atoms is substantially constant between the beginning of crystallization and solidification of about 50% of the feedstock silicon.

To produce a P-type crystallized silicon, the type and quantity of added dopants has to enable the following equation to be complied with, from the beginning of crystallization until at least 50% of the silicon is crystallized:

0.1 ppma≦ΣkₐC₀ₐ(1−x)^{k}^{ₐ}⁻¹−Σk_{d}C_{0d}(1−x)^{k}^{_{d}}⁻¹≦5 ppma (1).

The same is true for production of an N-type crystallized silicon, the added dopants having to enable the following equation to be complied with

0.1 ppma≦Σk_{d}C_{0d}(1−x)^{k}^{_{d}}⁻¹−ΣkₐC₀ₐ(1−x)^{k}^{ₐ}⁻¹≦5 ppma (2).

In these equations,
kₐ, k_{d} correspond to the segregation coefficients respectively of the acceptor doping elements and of the donor doping elements,
C₀ₐ, C_{0d} respectively correspond to the concentrations of acceptor doping elements and of donor doping elements in the molten silicon at the beginning of crystallization,
x corresponds to the fraction of crystallized silicon.

Concentrations C₀ₐ, C_{0d} comprise the quantities of dopants initially present in the feedstock and the predefined quantities of dopants necessary to satisfy the equations of the type of silicon produced which have been added thereto.

Control of the doping profiles of the donor and accept or atoms thereby enables the electrical type of the ingot to be defined and thus delays or prevents a change of type in the ingot. Furthermore, the use of a concentration difference of less than 5 ppma between the donor atoms and the acceptor atoms enables a high degree of compensation to be obtained, i.e. a low concentration difference between the donor atoms and the acceptor atoms. It has been discovered that this compensation, which is used in addition to the profile control to delay the change of type of the silicon ingot, enables the electrical performances of the silicon to be improved. Unlike what is commonly admitted, it was noticed that the use of a silicon having high dopant concentrations and which is highly compensated presents electrical performances compatible with use in photovoltaics or even presents better electrical performances than a non-compensated photovoltaic grade silicon. This improvement of the electrical properties is attributed to the use of a silicon comprising large quantities of dopants and a high compensation, and therefore a low concentration difference between the types of dopant. This surprising effect was observed several times on highly compensated areas of several ingots.

In general manner, the type and quantity of doping impurities that are added to the feedstock modify the donor and/or acceptor doping profile as a function of the height of the crystallized ingot. In this way, the difference between these two profiles is always comprised between 0.1 and 5 ppma over at least 50% of the crystallized silicon, i.e. in this area of the silicon, the concentration difference between donor atoms and acceptor atoms is always comprised between 0.1 and 5 ppma.

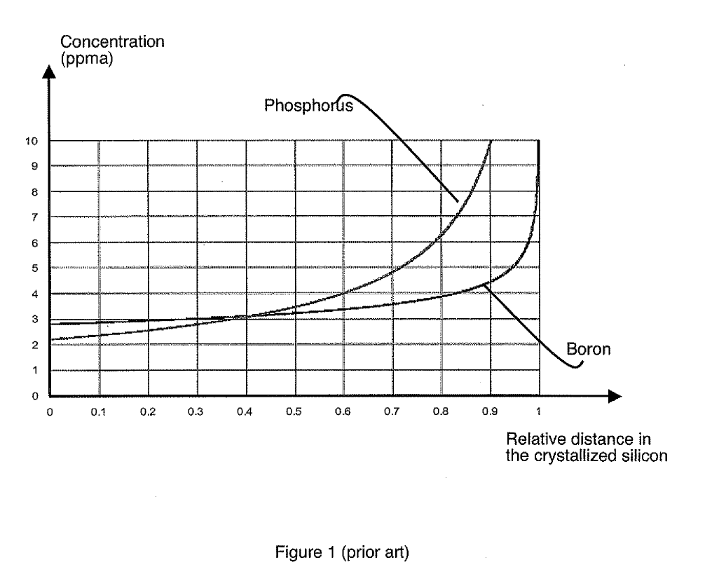

As an example, the silicon feedstock presents initial boron and phosphorus concentrations respectively equal to 3.5 atomic ppm and 6.3 atomic ppm and a P-type silicon is desired over at least the first 50% of the crystallized silicon. The segregation coefficients of boron and phosphorus being respectively equal to 0.8 and 0.35, resulting in the silicon in solid phase at the beginning of crystallization respectively containing 2.8 ppma and 2.2 ppma of boron and phosphorus. As illustrated in FIG. 1, the boron concentration is larger than the phosphorus concentration over the first 40% of the crystallized silicon. The difference in concentration is lower than 1 ppma over this part of the crystallized silicon. The crystallized silicon therefore presents a difference of concentration between the doping elements that satisfies the above-mentioned criteria for photovoltaic use, but the silicon changes doping type too early in crystallization which is a drawback.

In order to obtain a concentration difference that is always substantially lower than or equal to 2 ppma between the donor atoms and acceptor atoms over at least 50% of the crystallized silicon, gallium and phosphorus are added to the silicon feedstock. Arsenic and phosphorus having substantially identical segregation coefficients, respectively 0.3 and 0.35, it is possible to use arsenic, phosphorus or a mixture of the latter with gallium.

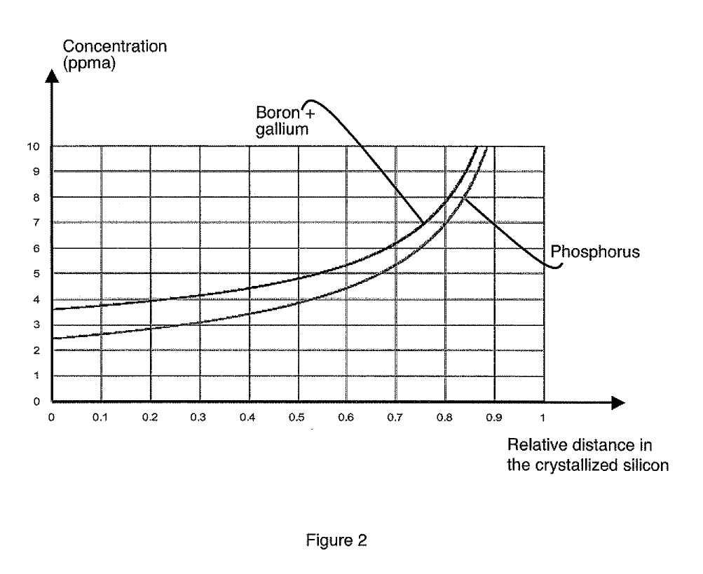

Predefined quantities of gallium and phosphorus (and/or of arsenic) are added to the feedstock so that the gallium and phosphorus concentrations in the feedstock are respectively equal to 100 ppma and 7 ppma. The boron concentration is unchanged. Under these conditions, as illustrated in FIG. 2, the concentration difference between the donor and acceptor atoms is less than 2 ppma over at least 85% of the silicon obtained. At the beginning of crystallization, the concentration of donor atoms (phosphorus or arsenic) is substantially equal to 2.45 ppma and the concentration of acceptor atoms (boron and gallium) is substantially equal to 3.6 ppma. As crystallization of the silicon progresses, the concentrations of donor and acceptor atoms change but the difference remains lower than 2 ppma, and when 80% of the silicon has been crystallized, the concentration of donor atoms is substantially equal to 7 ppma and the concentration of acceptor atoms is substantially equal to 7.9 ppma.

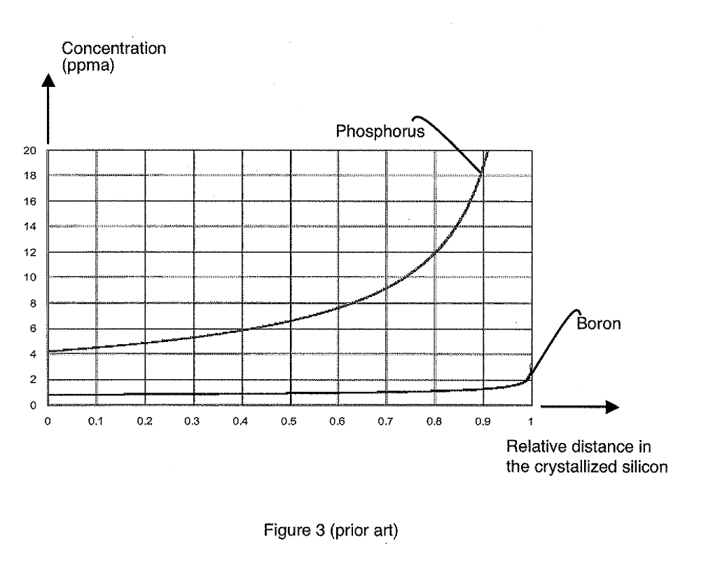

In another example, the silicon feedstock presents boron and phosphorus concentrations respectively equal to 1 atomic ppm and 12 atomic ppm and an N-type N silicon is desired over at least the first 50% of the crystallized silicon. The segregation coefficients of boron and phosphorus being respectively equal to 0.8 and 0.35, this results in the silicon in solid phase at the beginning of crystallization respectively containing 0.8 ppma and 4.2 ppma of boron and phosphorus. As illustrated in FIG. 3, the phosphorus concentration is always higher than the boron concentration in the crystallized silicon. The concentration difference is less than 5 ppma over about 40% of the crystallized silicon and is higher than this value over the rest of the crystallized silicon. The crystallized silicon therefore presents a difference between dopants that is too large in the top part of the ingot for a use in photovoltaics.

in order to obtain a concentration difference of less than 5 ppma and preferably substantially equal to 2 ppma between the donor atoms and acceptor atoms, gallium is added to the silicon feedstock.

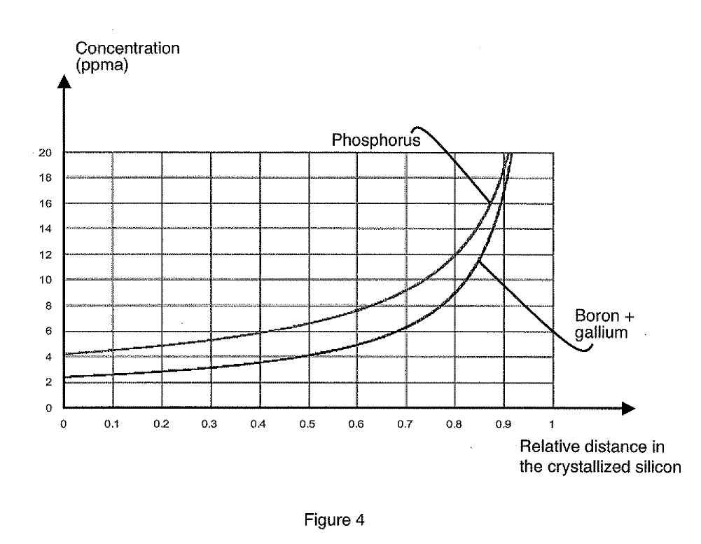

A predefined quantity of gallium is added to the feedstock so that the gallium concentration in the feedstock is equal to 200 ppma. The boron concentration is unchanged. Under these conditions, as illustrated in FIG. 4, an N-type silicon with a difference of concentrations between donor and acceptor atoms of less than 5 ppma is obtained from the beginning of growth up to the consumption of 50% of the feedstock silicon. At the beginning of crystallization, the donor atom concentration is substantially equal to 4.2 ppma and the acceptor atom concentration is substantially equal to 2.4 ppma. As crystallization of the silicon progresses, the donor atom and acceptor atom concentrations progress in substantially the same way, and when 50% of the silicon has been crystallized, the donor atom concentration is substantially equal to 6.6 ppma and the acceptor atom concentration is substantially equal to 4.1 ppma.

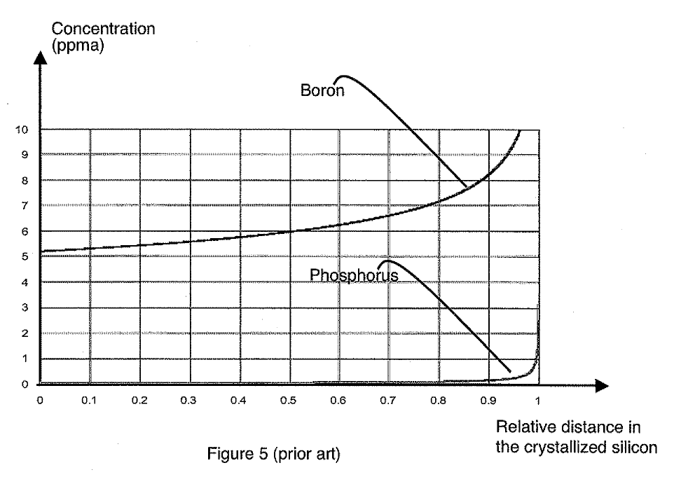

In another example, the silicon feedstock presents boron and phosphorus concentrations respectively equal to 6.5 ppm atomic and 0.1 ppm atomic and a P-type silicon is desired over at least the first 50% of the crystallized silicon. The segregation coefficients of boron and phosphorus being respectively equal to 0.8 and 0.35, resulting in the silicon in solid phase at the beginning of crystallization respectively containing 5.2 ppma and 0.035 ppma of boron and phosphorus. As illustrated in FIG. 5, the boron concentration is always higher than the phosphorus concentration in the crystallized silicon. The concentration difference is larger than 5 ppma over all of the crystallized silicon. The crystallized silicon therefore presents a difference between dopants that is too large for a use in photovoltaics.

In order to obtain a concentration difference of less than 5 ppma and preferably substantially equal to or less than 3 ppma between donor atoms and acceptor atoms, antimony is added to the silicon feedstock.

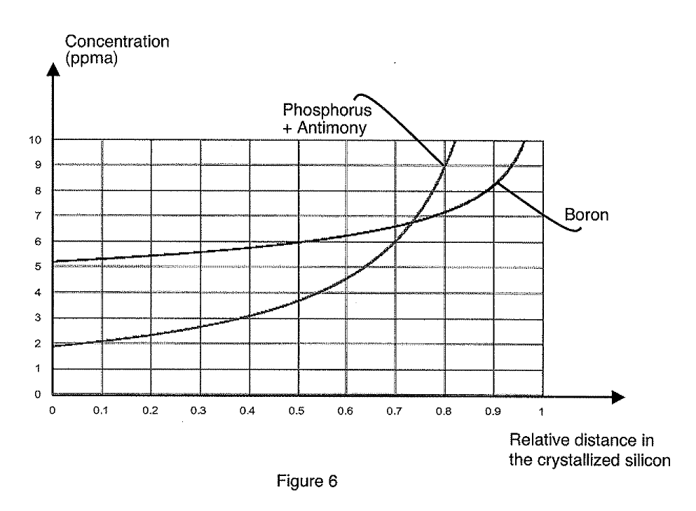

A predefined quantity of antimony is added to the feedstock so that the antimony concentration in the feedstock is equal to 80 ppma. The boron concentration is unchanged. Under these conditions, as illustrated in FIG. 6, a P-type silicon with a difference of concentrations between donor and acceptor atoms substantially equal to or less than 3 ppma is obtained from the beginning of growth up to the consumption of at least 50% of the feedstock silicon. At the beginning of crystallization, the acceptor atom concentration is substantially equal to 52 ppma and the donor atom concentration is substantially equal to 1.9 ppma. As crystallization of the silicon progresses, the donor and acceptor atom concentrations progress, and when 73% of the silicon has been crystallized, the donor and acceptor atom concentrations are substantially equal to 6.8 ppma and the silicon is said to be compensated.

In yet another example, the silicon feedstock presents boron and phosphorus concentrations respectively equal to 10 ppm atomic and 24 ppm atomic and an N-type silicon is desired over at least the first 50% of the crystallized silicon. The segregation coefficients of boron and phosphorus being respectively equal to 0.8 and 0.35, resulting in the crystallized silicon being of N-type but the compensation not being sufficient. The phosphorus concentration is in fact much too high compared with that of the boron, the concentration difference being larger than 5 ppma over the entire crystallized silicon. The crystallized silicon therefore presents a difference between the dopants that is too large for use in photovoltaics.

To obtain a concentration difference of less than 5 ppma, phosphorus and gallium are added to the silicon feedstock.

Predefined quantities of phosphorus and gallium are added to the feedstock so that the phosphorus concentration in the feedstock is equal to 33 ppma and the gallium concentration is equal to 440 ppma. The boron concentration is unchanged at 10 ppma. Under these conditions, an N-type silicon with a difference of concentrations between donor and acceptor atoms that is compatible with use in photovoltaics is obtained for 95% of the crystallized silicon.

It should be noted that for boron concentrations of more than 15 ppma, it is difficult to obtain an N-type ingot over almost the entire height of the crystallized silicon according to the predefined criteria. Likewise, it is difficult is to obtain a P-type ingot over almost all of the crystallized silicon according to the predefined criteria for boron concentrations of more than 20 ppma. For a feedstock comprising between 5 and 15 ppma of boron, it is therefore possible to easily obtain an N-type crystallized silicon by adding other dopants and for a feedstock comprising between 5 and 20 ppma of boron, it is also possible to easily obtain a P-type crystallized silicon according to the added dopants. These two types of silicon naturally satisfy the conditions set out in the above.

The method according to the invention can also be used for producing monocrystalline silicon ingots by the Czochralski or float zone method, or multicrystalline silicon by directional solidification. The method can also be used in production of multicrystalline silicon ribbons from a molten silicon bath.

In general manner, at least a predefined quantity of a doping element having a segregation coefficient less than or equal to 0.1 is thus added to the silicon feedstock before crystallization of the latter. It is also possible to add at least two different doping elements which present different segregation coefficients. The silicon feedstock described in the examples is of metallurgical type, but it can also be of purified metallurgical type, of highly-doped solar type or of highly-doped electronic type. In all cases, the silicon feedstock contains at least 0.1 ppma of doping impurities.

As explained in the foregoing, it is particularly difficult to eliminate doping impurities, in particular boron and phosphorus, in silicon feedstocks, which explains the high cost of solar grade silicon and microelectronic grade silicon. It is therefore particularly advantageous from an economic point of view to add one or more dopants to foster a single type of conductivity over most of the crystallized silicon. It is also advantageous to use compensation of the main dopant to limit apparent doping of the main dopant by using at least two dopants of opposite types. In this way, by adding predefined quantities of dopants to those already present in the feedstock, it is possible to control the electron donor and acceptor element concentration profiles, and therefore the difference between these two types of impurities Cₐ−C_{d} over a large part of the ingot.

With this crystallization method, the price of crystallized silicon depends on the price of the silicon that composes the initial feedstock, the purer the initial silicon the higher the final price. However, the higher the dopant concentrations in the initial feedstock, the more these dopants will be present in the crystallized silicon.

A large number of publications give the maximum dopant concentrations that are accepted in a photovoltaic grade silicon. It is typically admitted that the concentration of phosphorus atoms is lower than 0.09 ppma and exceptionally lower than 0.63 ppma. It is also stated that, in a photovoltaic grade silicon, the boron concentration is lower than 0.8 ppma. Such values can be found in the “Handbook of Photovoltaics Science and Engineering” chapter 5, page 177, table 5.5, in the article by Yuge et al. “Purification of Metallurgical Grade Silicon up to Solar Grade”, Progress in Photovoltaics, 2001, Vol. 9, page 204. In the present photovoltaic cell, the dopant concentrations are considerably higher than these commonly stated limits.

It is apparent from these ascertainments that the quantity of material able to be used for a photovoltaic application is also dependent on the quantity of dopants contained in the initial silicon feedstock. The higher the dopant concentrations, the more limited the quantity of usable material. A trade-off therefore has to be made between the quality of the initial feedstock in dopants, i.e. the price and initial quantity of dopants, and the quantity of usable material once the silicon has been crystallized.

It has surprisingly been discovered that for a silicon feedstock in which one or more dopants have been added, for example an addition of gallium and/or phosphorus, to satisfy one or another of the foregoing two equations, an improvement of the electrical performances of the silicon exists in the crystallized silicon. It is thus possible to obtain a crystallized silicon that is compatible with use in photovoltaics, by means of a feedstock containing a large quantity of dopants and which is therefore inexpensive. The silicon obtained that is compatible with a use in photovoltaic presents a donor dopant element and/or an acceptor dopant element concentration larger than 5 ppma and a difference between the donor and acceptor element concentrations of less than 5 ppma, but still in favour of the same type of elements. For a P-type silicon, the electron acceptor atom concentration, typically the Boron concentration, is larger than or equal to 5 ppma. For an N-type silicon, the electron donor atom concentration, typically the Phosphorus concentration, is larger than or equal to 5 ppma. This silicon is particularly advantageous in the case where the boron and/or phosphorus concentrations are larger than 5 ppma and even more particularly advantageous when these concentrations are larger than 10 ppma, as the conversion efficiencies at cell level are compatible with a use in photovoltaics and the cost is more reduced than the constraints on the initial silicon feedstock are reduced. In general manner, it is observed that the problem involved in obtaining a silicon ingot under the conditions set out above arises from the boron concentration, even for obtaining an N-type ingot. If the boron concentration is very low, the ingot can comprise a large phosphorus concentration without co-doping being necessary. On the contrary, in the case of a high boron concentration, if it is desired to obtain an N-type silicon ingot, phosphorus and gallium have to be added to satisfy the above-mentioned conditions for obtaining a silicon compatible with a use in photovoltaics.

This improvement of the electrical characteristics results in an increase of the lifetime of the charge carriers generated in the silicon. This improvement has the immediate effect of increasing the expected conversion efficiency for the photovoltaic cells produced from this silicon. This result is in contradiction with what is theoretically expected for this type of crystalline silicon which comprises very large quantities of doping impurities and for which a degradation of the electrical performances is theoretically expected. This improvement is visible for photovoltaic cells using single-crystal or polycrystalline silicon. It therefore becomes possible to obtain an inexpensive photovoltaic grade silicon by combining an economical production method and a considerably cheaper initial feedstock than its equivalents of photovoltaic and electronic grade. In this particularly surprising and advantageous embodiment, improvement of the characteristics of the final silicon is linked to the addition of dopants to obtain compensation and not to elimination of dopants as in conventional approaches.

In this way, the method presented above is particularly advantageous for obtaining an inexpensive photovoltaic grade silicon. The quality criteria on the initial feedstock are reduced (for the dopants) and the use of a high so compensation enables photovoltaic cells to be designed with a base of silicon presenting high dopant concentrations.

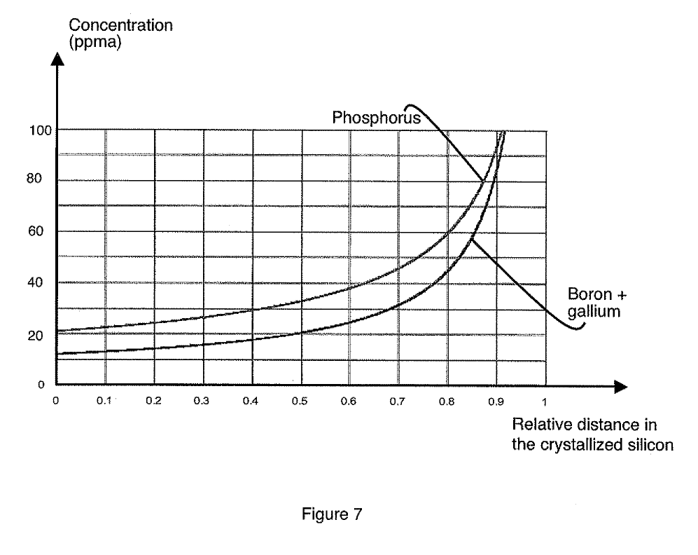

For example purposes as illustrated in FIG. 7, a crystalline silicon showing very good electrical properties can be obtained from a metallurgical grade silicon feedstock comprising between 5 and 25 ppma of boron, here 20 ppma of boron. Phosphorus and gallium are added to this feedstock to satisfy equation (2). Here, 42 ppma of phosphorus and 560 ppma of gallium were added to the feedstock. When crystallization takes place, the silicon does not change type, and the concentration difference is less than or equal to 5 ppma over 80% of the height of the crystallized silicon.

An equivalent result can be obtained for a crystallized silicon that is N-type, i.e. the electron donor atom concentration whereof is higher than the electron acceptor atom concentration.

To achieve a competitive conversion efficiency, the silicon of the photovoltaic cell advantageously presents a boron concentration that is lower than or equal to 25 ppma and/or a phosphorus (or arsenic) concentration lower than or equal to 100 ppma and/or a gallium concentration lower than or equal to 100 ppma. These limits are theoretical and can be exceeded depending on the required conversion efficiency.

II is also possible, with other techniques, to obtain a photovoltaic grade silicon presenting a concentration at least equal to 5 ppma of donor and/or acceptor atoms and a difference that is less than or equal to 5 ppma between these dopants. It is possible to perform such dopings by dopant implantation and annealing, by epitaxy and annealing or by gas doping and annealing. In all these approaches, it is necessary to start off from a silicon substrate that presents a constant doping level over the whole thickness of the silicon. This silicon substrate is then doped, the required dopants then being added. If the dopant profiles during the doping step do not satisfy the conditions set out above, the substrate is annealed to achieve homogenization of the dopant levels. Although these approaches are possible, they are not economic as they initially require particular substrates that are costly and each additional step increases the cost price of the final silicon.

1. Silicon-based photovoltaic cell wherein the silicon comprises a concentration of donor dopant elements and/or of acceptor dopant elements larger than or equal to 5 ppma, the difference between these two concentrations being less than or equal to 5 ppma.

2. Photovoltaic cell according to claim 1, wherein the boron concentration is larger than or equal to 5 ppma.

3. Photovoltaic cell according to claim 1, wherein the phosphorus concentration is larger than or equal to 5 ppma.

4. Method for producing photovoltaic grade crystalline silicon by crystallization of a molten silicon feedstock, method wherein the sum of the initial concentrations of donor dopant elements and acceptor dopant elements in the silicon feedstock is larger than 0.1 ppma, both the acceptor and donor dopant element concentrations being lower than 25 ppma, the method comprises before crystallization of the silicon:
determining the concentrations of donor-type and acceptor-type doping material initially present in the feedstock,
adding at least a predefined quantity of a doping material having a segregation coefficient of less than 0.1 so as to comply, over at least 50% of the crystallized silicon from the beginning of crystallization, either with a first equation for a P-type crystalline silicon
0.1 ppma≦ΣkₐC₀ₐ(1−x)^{k}^{_{d}}⁻¹−Σk_{d}C_{0d}(1−x)^{k}^{_{d}}⁻¹≦5 ppma
or with a second equation for an N-type crystalline silicon
0.1 ppma≦Σk_{d}C_{0d}(1−x)^{k}^{_{d}}⁻¹−ΣkₐC₀ₐ(1−x)^{k}^{ₐ}⁻¹≦5 ppma,
equations in which
kₐ, k_{d} correspond to the segregation coefficients respectively of the acceptor dopant elements and of the donor dopant elements,
C₀ₐ, C_{0d} correspond respectively to the concentrations of acceptor dopant elements and of donor dopant elements in the molten silicon just before crystallization,
x corresponds to the fraction of crystallized silicon.

5. Method according to claim 4, wherein the doping material having a segregation coefficient of less than 0.1 is chosen from gallium, antimony, indium and bismuth.

6. Method according to claim 4, comprising addition of boron, phosphorus, arsenic, aluminium and/or tin before crystallization to satisfy the equation corresponding to the type of crystalline silicon produced.

7. Method according to claim 4, wherein the sum of the initial concentrations of donor doping elements dopants and of acceptor doping elements is larger than 5 ppma.

8. Method according to claim 7, wherein the boron concentration being comprised between 5 and 20 ppma, the crystalline silicon obtained is of P type.

9. Method according to claim 7, wherein the boron concentration being comprised between 5 and 15 ppma, the crystalline silicon obtained is of N type.
